(19) United States
(12) Patent Application Publication
(10) Pub. No.: US 2007/0296984 A1
(43) Pub. Date: Dec. 27, 2007

(54) System and method for device specific color space conversion

(75) Inventor: William C. Kress, Mission Viejo, CA (US)

Correspondence Address: TUCKER ELLIS & WEST LLP, 1150 HUNTINGTON BUILDING, 925 EUCLID AVENUE, CLEVELAND, OH, 44115-1414, US

(73) Assignees: Kabushiki Kaisha Toshiba; Toshiba Tec Kabushiki Kaisha

(21) Appl. No.: 11/471,816

(22) Filed: Jun. 21, 2006

(51) Int. Cl. G03F 3/08

(52) U.S. Cl. 358/1.9; 358/518

(57) ABSTRACT

The subject application is directed generally to color conversions and more particularly, to color space conversions for electronic images. The subject application is particularly applicable to conversions made prior to rendering of images by output devices, such as printers, wherein an image encoded in a first multidimensional color space is to be converted to a color space associated with output device prior to rendering.

### BACKGROUND OF THE INVENTION

The subject application is directed generally to color conversions and more particularly, to color space conversions for electronic images. The subject application is particularly applicable to conversions made prior to rendering of images by output devices, such as printers, wherein an image encoded in a first multidimensional color space is to be converted to a color space associated with output device prior to rendering. However, it will be appreciated that the subject method and system is applicable to any conversion between color spaces wherein optimized output directed to a target document processor is desired.

Earlier color image rendering systems frequently employ images that are described numerically relative to primary color components. Such color components are suitably additive in nature, such as red-green-blue (RGB), or subtractive, such as cyan, yellow, magenta (CYM), the latter of which is frequently coupled with a black color (K), referred to as CYMK or CYM(K). Additive primary color space descriptions are generally associated with images displayed on light generating devices, such as monitors or projectors. Subtractive primary color space descriptions are generally associated with images generated on non-light generating devices, such as paper printouts. In order to move an image from a display to a fixed medium, such as paper, a conversion must be made between color spaces associated with electronic encoding of documents.

The concepts disclosed herein are better appreciated with an understanding of numeric models used to represent images, and image colorization, in image processing or rendering applications. One of the first mathematically defined color spaces was the CIE XYZ color space (also known as CIE 1931 color space), created by CIE in 1931. A human eye has receptors for short (S), middle (M), and long (L) wavelengths, also known as blue, green, and red receptors. One need only generate three parameters to describe a color sensation. A specific method for associating three numbers (or tristimulus values) with each color is called a color space, of which the CIE XYZ color space is one of many such spaces. The CIE XYZ color space is based on direct measurements of the human eye, and serves as the basis from which many other color spaces are defined.

In the CIE XYZ color space, tristimulus values are not the S, M and L stimuli of the human eye, but rather a set of tristimulus values called X, Y, and Z, which are also roughly red, green and blue, respectively. Two light sources may be made up of different mixtures of various colors, and yet have the same color (metamerism). If two light sources have the same apparent color, then they will have the same tristimulus values irrespective of what mixture of light was used to produce them.

CIE L*a*b* (CIELAB or Lab) is frequently thought of as one of the most complete color models. It is used conventionally to describe all the colors visible to the human eye. It was developed for this specific purpose by the International Commission on Illumination (Commission Internationale d'Eclairage, resulting in the acronym CIE). The three parameters (L, a, b) in the model represent the luminance of the color (L: L=0 yields black and L=100 indicates white), its position between red and green (a: negative values indicate green, while positive values indicate red), and its position between yellow and blue (b: negative values indicate blue and positive values indicate yellow).

The Lab color model has been created to serve as a device independent reference model. It is therefore important to realize that visual representations of the full gamut (available range) of colors in this model are not perfectly accurate, but are used to conceptualize a color space. Since the Lab model is three dimensional, it is represented properly in a three dimensional space. A useful feature of the model is that the first parameter is extremely intuitive: changing its value is like changing the brightness setting in a TV set. Therefore only a few representations of some horizontal “slices” in the model are enough to conceptually visualize the whole gamut, wherein the luminance is suitably represented on a vertical axis.

The Lab model is inherently parameterized correctly. Accordingly, no specific color spaces based on this model are required. CIE 1976 L*a*b* or Lab mode is based directly on the CIE 1931 XYZ color space, which sought to define perceptibility of color differences. Circular representations in Lab space correspond to ellipses in XYZ space. Non-linear relations for L*, a*, and b* are related to a cube root, and are intended to mimic the logarithmic response of the eye. Coloring information is referred to the color of the white point of the system.

Electronic documents, such as documents that describe color images, are typically encoded in one or more standard formats. While there are many such formats, representative descriptions currently include Microsoft Word file (*.doc), tagged information file format (“TIFF”), graphic image format (“GIF”), portable document format (“PDF”), Adobe Systems' PostScript, hypertext markup language (“HTML”), extensible markup language (“XML”), drawing exchange files (*.dxf), drawing files (*.dwg), Paintbrush files (*.pcx), Joint Photographic Expert Group (“JPEG”), as well as a myriad of other bitmapped, encoded, compressed or vector file formats.

As noted above, there is a need to convert between color spaces prior to rendering of a document output. In an International Color Consortium (“ICC”) system, an input is formed as an input profile, and an output is formed as an output profile. In general, conversion is made from input color space, such as red-green-blue (“RGB”) to a profile connection space. The profile connection space in turn is converted to an output space, such as CMYK.

In Adobe Systems' PostScript, a commonly used file format, level 3 allows for theoretically unlimited color management. It uses an internal file format referred to as a dictionary. The dictionary designates an input profile as a color space array and an output profile as a color rendering dictionary. The ICC has created a number of standard tags that allow for conversion of ICC profiles to color space arrays or color rendering dictionaries. The level 3 standard leaves it to software designers to generate or read the color space array. A driver is typically used to generate a color rendering dictionary from an ICC color profile.

In Adobe Systems' Photoshop, conversion between input and output is accomplished via a monitor table that converts between values, such as monitor RGB and Lab, via a monitor table. Lab values are converted to an output, such as CMYK via separation table.

In addition to the forgoing, direct conversions between color spaces have been made using device link profiles, which function to convert directly between color spaces using predefined lookup tables. With such a conversion system, a descriptor having a value in an initial or primary color space is communicated to a color lookup table which, in turn, returns a color description in a second color space associated with a document output device.

Lookup tables used in earlier conversions are populated according to standard conversion algorithms or accepted conversion factors. However, there is a substantial variation in the characteristics associated with various output devices, such as ink jet printers, color laser printers, and the like. Such variation may be attributed to mechanical, physical or chemical properties associated with a document rendering operation. Such operations may include peculiarities of the rendering engine themselves, an available palette of colors from which an image will ultimately be rendered, physical properties of material, such as paper, toner characteristics, toner color options, fixation characteristics and properties of electrical or electrostatic charges used in image generation. Additionally, combinations such as interaction between a type of toner with a particular paper, will affect an output image. Thus, variation may be attributed to mechanical, physical or chemical properties associated with a document rendering operation.

In accordance with the foregoing, there is substantial variation among ultimately realized output on document rendering devices. It would be advantageous to have a document rendering device that resulted in an image output that is substantially truer to that of the original description, such with an image displayed on a CRT or monitor during the process of building an electronic document. Further, device characteristics teaches an improved conversion system which optimizes an output in connection with properties of a document output device, as well as provides a mechanism by which particular effects desired by a user may be implemented in such a document output.

### SUMMARY OF THE INVENTION

In accordance with the subject application, there is provided a system and method for device specific color conversions.

Further, in accordance with the subject application there is provided a system and method for color space conversion which optimizes an output in connection with properties of a document output device, as well as provides a mechanism by which particular effects desired by a user may be implemented in such a document output.

Still further, in accordance with the subject application, there is provided a color conversion system, wherein such system comprises means adapted for receiving source parameter data representative of an input color gamut of a first multidimensional color space. The system also comprises means adapted for receiving empirical parameter data associated with color output properties of an associated document output device, which empirical parameter data is associated with a second multidimensional color space. The system further comprises conversion table generation means adapted for generating a device link profile in accordance with the source parameter data and the empirical parameter data.

Preferably, the empirical data includes data corresponding to toner characteristics associated with the document output device.

In one embodiment, the conversion table generation means includes means adapted for generating a three dimensional data table corresponding to a mapping between the first multidimensional color space and the second multidimensional color space. In addition, the color table generation means also includes means adapted for defining a base white value at a first vertex of the three dimensional table and means adapted for defining a base black value in accordance with a second vertex of the three dimensional table. The color table generation means further comprises means adapted for defining values associated with surfaces of the three dimensional table in accordance with maximum values associated with the second multidimensional color space and means adapted for altering values associated with color progression between vertices of the three dimensional table in accordance with the empirical data.

In another embodiment, the system also includes means adapted for receiving mode data representative of desired output characteristics associated with the conversion. In addition, the conversion table generation means further includes means adapted for generating the device link profile in accordance with the mode data. Mode data includes a myriad of possible effects, and includes such output options including photo, match screen, web colors, vivid, sepia, comic book, soft and natural effects.

In yet another embodiment, the first multidimensional color space is RGB and wherein the second multidimensional color space is CYMK, and wherein vertices of the three dimensional table further define base values associated with cyan, yellow, magenta, red, green and blue.

Still further, in accordance with the subject application, there is provided a method for color space conversion in accordance with the above described system.

Still other advantages, aspects and features of the subject application will become readily apparent to those skilled in the art from the following description wherein there is shown and described a preferred embodiment of this invention, simply by way of illustration of one of the best modes best suited to carry out the invention. As it will be realized, the invention is capable of other different embodiments and its several details are capable of modifications in various obvious aspects all without departing from the scope of the invention. Accordingly, the drawings and descriptions will be regarded as illustrative in nature and not as restrictive.

### BRIEF DESCRIPTION OF THE DRAWINGS

FIG. 1 illustrates a networked document processing environment employed in the color space conversion of the preferred embodiment;

FIG. 2 illustrates a document output controller on which the subject color space conversion is completed in the preferred embodiment;

FIG. 3 illustrates functional operation of the controller of FIG. 2;

FIG. 4 illustrates an overall system for generating a device specific, device link profile to facilitate conversion between color spaces in the preferred embodiment;

FIG. 5 illustrates a conversion between color spaces of the preferred embodiment; and

FIG. 6 illustrates a cubic color space conversion array used in connection with a conversion of the preferred embodiment.

### DETAILED DESCRIPTION OF THE PREFERRED EMBODIMENT

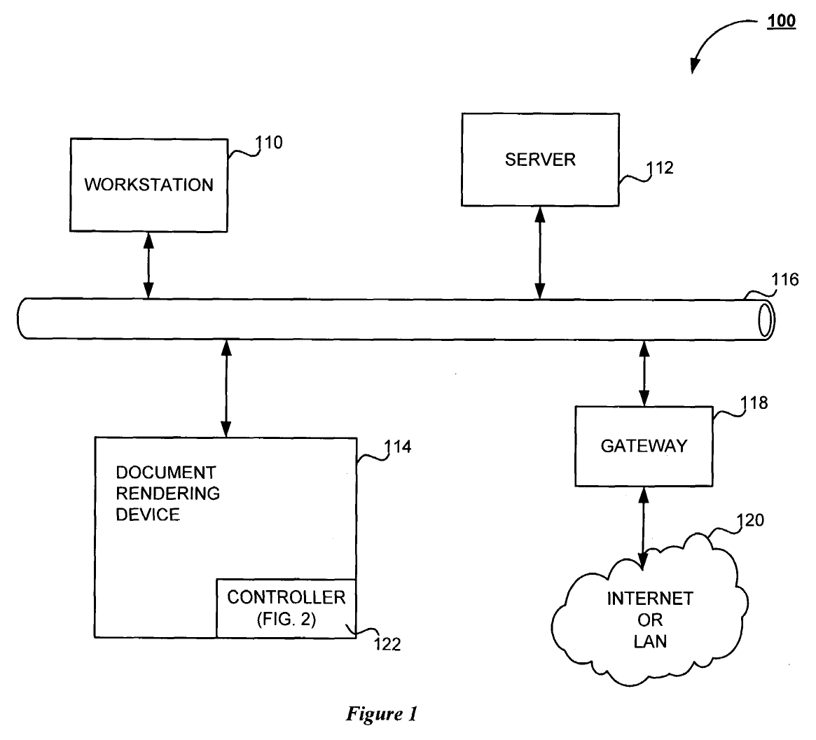

Turning now to the drawings wherein the illustrations are for purposes of illustrating the preferred embodiment only, and not for the purpose limiting the same, illustrated is a document processing environment 100, suitably comprised of a shared-peripheral document processing environment, such as would be expected in an office. In the illustration of FIG. 1, included is a workstation 110, a server 112 and a document rendering device 114, all in mutual data communication via a local area network 116. It will be appreciated by those skilled in the art that the network 116 is any distributed communications environment known in the art capable of enabling the exchange of data between two or more electronic devices. Those skilled in the art will further appreciate that the network 116 is any computer network known in the art including, for example and without limitation, a virtual area network, a local area network, a personal area network, the Internet, an intranet, a wide area network, or any suitable combination thereof. Preferably, the network 116 is comprised of physical layers and transport layers, as illustrated by the myriad of conventional data transport mechanisms, such as, for example and without limitation, Token-Ring, 802.11(x), Ethernet, or other wireless or wire-based data communication mechanisms.

Such a typical office environment also includes a gateway 118 by which devices on the network can communicate to external networks or devices, such as illustrated by Internet or WAN 120. As will be appreciated by the skilled artisan, a suitable gateway 118 employed in accordance with the present invention includes, WiMax, 802.11a, 802.11b, 802.11g, 802.11(x), Bluetooth, the public switched telephone network, a proprietary communications network, infrared, optical, or any other suitable wired or wireless data transmission communications known in the art.

The color space conversion of the subject application is suitably completed in a controller 122 of the document rendering device 114. However, it is to be appreciated that subject conversions which are software driven, are suitably completed in any processing device, such as workstation 110 or server 112.

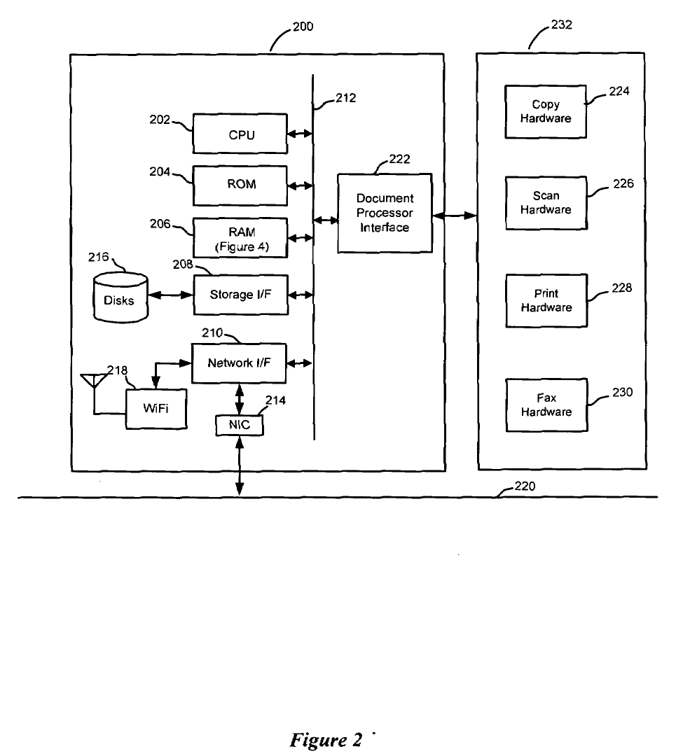

Turning now to FIG. 2, illustrated is a representative architecture of a suitable controller 200 on which operations of the subject system are completed. Included is a processor 202, suitably comprised of a central processor unit. However, it will be appreciated that processor 202 may advantageously be composed of multiple processors working in concert with one another as will be appreciated by one of ordinary skill in the art. Also included is a non-volatile or read only memory 204 which is advantageously used for static or fixed data or instructions, such as BIOS functions, system functions, system configuration data, and other routines or data used for operation of the controller 200.

Also included in the controller 200 is random access memory 206, suitably formed of dynamic random access memory, static random access memory, or any other suitable, addressable and writable memory system. Random access memory provides a storage area for data instructions associated with applications and data handling accomplished by processor 202.

A storage interface 208 suitably provides a mechanism for non-volatile, bulk or long term storage of data associated with the controller 200. The storage interface 208 suitably uses bulk storage, such as any suitable addressable or serial storage, such as a disk, optical, tape drive and the like as shown as 216, as well as any suitable storage medium as will be appreciated by one of ordinary skill in the art.

The subject system suitably operates on instructions and data that operate on processor 202, utilizing memory 206 and storage 216.

A network interface subsystem 210 suitably routes input and output from an associated network allowing the controller 200 to communicate to other devices. The network interface subsystem 210 suitably interfaces with one or more connections with external devices to the device 200. By way of example, illustrated is at least one network interface card 214 for data communication with fixed or wired networks, such as Ethernet, token ring, and the like, and a wireless interface 218, suitably adapted for wireless communication via means such as WiFi, WiMax, wireless modem, cellular network, or any suitable wireless communication system. It is to be appreciated however, that the network interface subsystem suitably utilizes any physical or non-physical data transfer layer or protocol layer as will be appreciated by one of ordinary skill in the art. In the illustration, the network interface 214 is interconnected for data interchange via a physical network 220, suitably comprised of a local area network, wide area network, or a combination thereof.

Data communication between the processor 202, read only memory 204, random access memory 206, storage interface 208 and network interface subsystem 210 is suitably accomplished via a bus data transfer mechanism, such as illustrated by bus 212.

Also in data communication with bus 212 is a document processor interface 222. Document processor interface 222 suitably provides connection with hardware 232 to perform one or more document processing operations. Such operations include copying accomplished via copy hardware 224, scanning accomplished via scan hardware 226, printing accomplished via print hardware 228, and facsimile communication accomplished via facsimile hardware 230. It is to be appreciated that a controller suitably operates any or all of the aforementioned document processing operations. Systems accomplishing more than one document processing operation are commonly referred to as multifunction peripherals or multifunction devices.

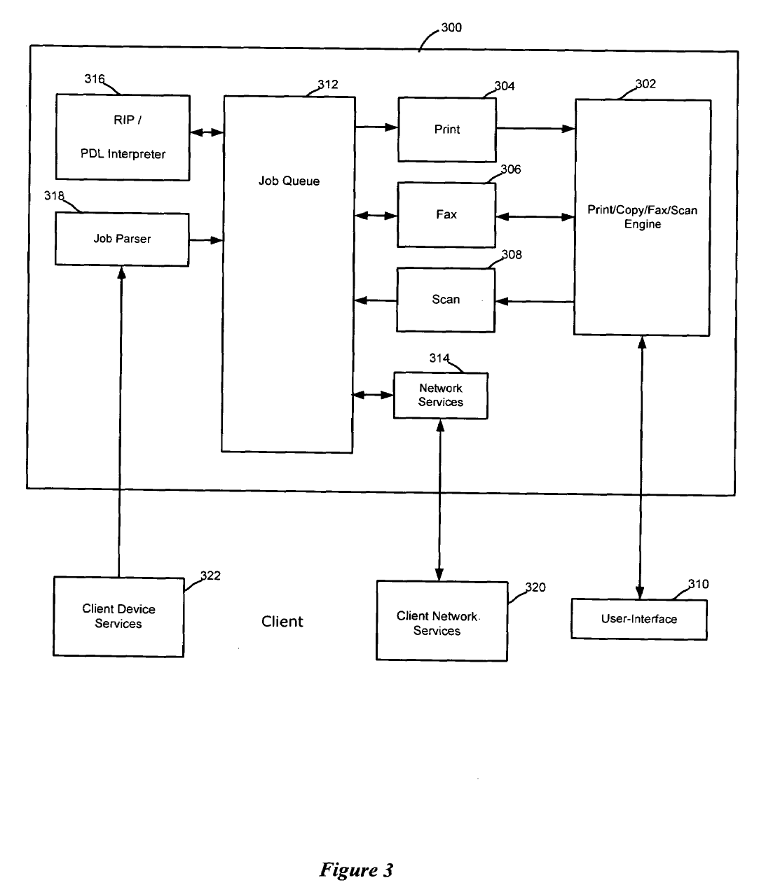

Functionality of the subject system is accomplished on a suitable document processing device that includes a controller of FIG. 2 as an intelligent subsystem associated with a document processing device. In the illustration of FIG. 3, controller function 300 in the preferred embodiment includes a document processing engine 302. A suitable controller functionality is that incorporated into the Toshiba e-Studio system in the preferred embodiment. FIG. 3 illustrates suitable functionality of the hardware of FIG. 2 in connection with software and operating system functionality as will be appreciated by one of ordinary skill in the art.

In the preferred embodiment, the engine 302 allows for printing operations, copy operations, facsimile operations and scanning operations. This functionality is frequently associated with multi-function peripherals, which have become a document processing peripheral of choice in the industry. It will be appreciated, however, that the subject controller does not have to have all such capabilities. Controllers are also advantageously employed in dedicated or more limited purposes document processing devices that are subset of the document processing operations listed above.

The engine 302 is suitably interfaced to a user interface panel 310, which panel allows for a user or administrator to access functionality controlled by the engine 302. Access is suitably via an interface local to the controller, or remotely via a remote thin or thick client.

The engine 302 is in data communication with printer function 304, facsimile function 306, and scan function 308. These devices facilitate the actual operation of printing, facsimile transmission and reception, and document scanning for use in securing document images for copying or generating electronic versions.

A job queue 312 is suitably in data communication with printer function 304, facsimile function 306, and scan function 308. It will be appreciated that various image forms, such as bit map, page description language or vector format, and the like, are suitably relayed from scan function 308 for subsequent handling via job queue 312.

The job queue 312 is also in data communication with network services 314. In a preferred embodiment, job control, status data, or electronic document data is exchanged between job queue 312 and network services 314. Thus, suitable interface is provided for network access to the controller 300 via client side network services 320, which is any suitable thin or thick client. In the preferred embodiment, the web services access is suitably accomplished via a hypertext transfer protocol, file transfer protocol, uniform data diagram protocol, or any other suitable exchange mechanism. Network services 314 also advantageously supply data interchange with client side services 320 for communication via FTP, electronic mail, TELNET, or the like. Thus, the controller function 300 facilitates output or receipt of electronic document and user information via various network access mechanisms.

Job queue 312 is also advantageously placed in data communication with an image processor 316. Image processor 316 is suitably a raster image process, page description language interpreter or any suitable mechanism for interchange of an electronic document to a format better suited for interchange with device services such as printing 304, facsimile 306 or scanning 308.

Finally, job queue 312 is in data communication with a parser 318, which parser suitably functions to receive print job language files from an external device, such as client device services 322. Client device services 328 suitably include printing, facsimile transmission, or other suitable input of an electronic document for which handling by the controller function 300 is advantageous. Parser 318 functions to interpret a received electronic document file and relay it to a job queue 312 for handling in connection with the afore-described functionality and components.

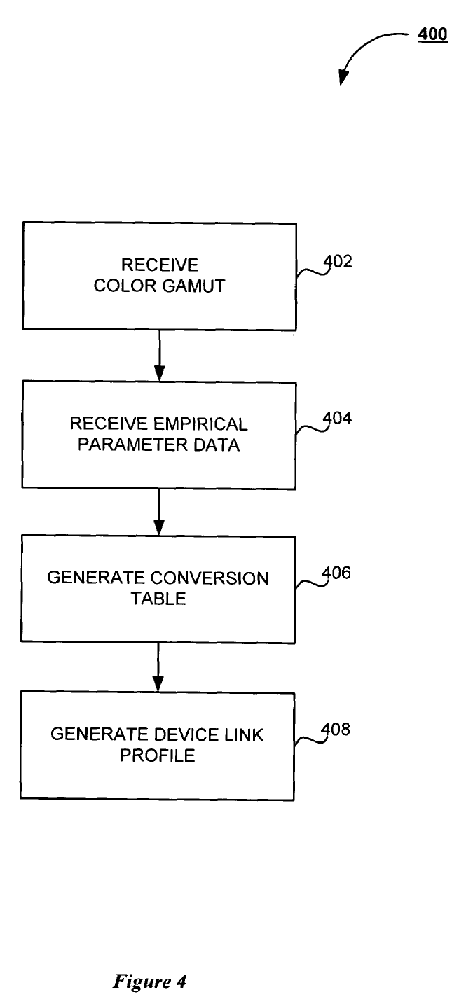

Turning now to FIG. 4, illustrated is the improved color space conversion as taught by the subject application. For purposes of the subject illustration, conversion is made from a device description provided in RGB to an output encoded in CMYK. Such a conversion is ubiquitous in the document processing industry. However, it will be appreciated that the subject system is advantageously employed between conversions among any color space descriptions.

Properties of document rendering devices, such as printers, laser printers, ink jet printers, as well as any other document rendering device, are associated with a set of parameters referred to as their gamut. A device gamut is the range of colors that can be reproduced given the physical and chemical properties associated with a document output device, image deposition materials or associated output media. As noted earlier, factors such as paper properties, toner options, toner properties and properties associated with a document rendering engine, will affect a gamut of a particular output device, or type or series of output devices. In the subject application, empirical information associated with a particular device gamut is acquired prior to populating a lookup table associated with a color space conversion. Such empirical data includes measurement of a complete output gamut associated with a particular device or family of devices.

Turning to FIG. 4, illustrated is an overall system for generating a device specific, device link profile to facilitate conversion in connection with the subject application. Application of such a device link profile to a conversion operation will be detailed below.

In FIG. 4, input relative to a color gamut associated with an electronic document is received in step 402. Next at step 404, empirically derived or measured parameter date is received. As noted above, such parameter data is suitably obtained empirically for a device, or class of similar devices. Next, at step 406, a conversion table to facilitate conversion between the input color gamut and the available color gamut of the output device or devices at issue is generated. In the preferred embodiment, a conversion is made between multidimensional color spaces, such that a resultant conversion table for a device link profile conversion is comprised of a three-dimensional lookup table.

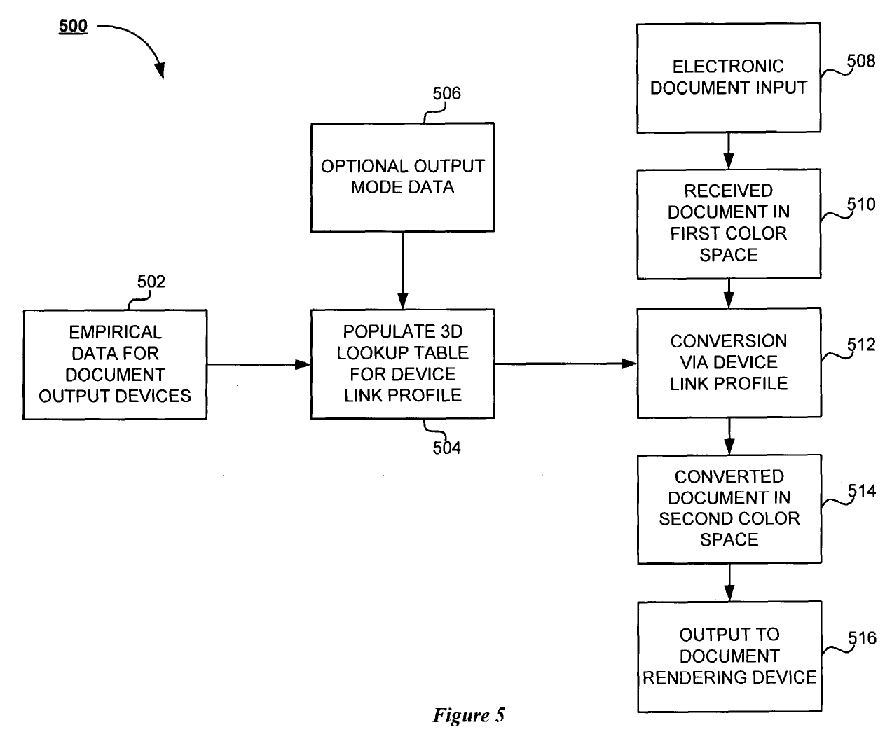

In the conversion system 500 of FIG. 5, such empirical data at block 502 is communicated to block 504 which functions to populate a three dimensional lookup table for color space conversion as taught in the preferred embodiment. Optionally, output mode data which will affect ultimate rendering and is selectable is input from block 506. A more detailed description of population of a lookup table as in block 504 and the use of optional output mode in block 506 will be given below.

Block 508 illustrates an input of an electronic document. At block 510, a received electronic document is available, which document is defined in a first encoded multidimensional color space. As noted above, in a representative conversion of the preferred embodiment, the document at block 510 is suitably encoded in an additive primary color space, such as RGB. This document is then communicated to block 512, which block has received a conversion mechanism, such as a device link profile, which incorporates empirical data as well as optional mode data as noted above. While the subject illustration is directed to a single-step conversion directly between color spaces, such as RGB to CMYK, it is to be appreciated that similar weighting of conversions that employ empirical data associated with one or more output devices are also suitably incorporated into multi-step conversions, such as RGB to CIE to CMYK.

Once a color space conversion is completed at block 512, block 514 illustrates that such document is now encoded in a second multidimensional color space, which document is advantageously converted taking improved advantage of output characteristics of a particular document output or rendering device. Next, the converted electronic document is communicated to block 516 for output from such a rendering device.

In earlier systems, output profiles, such as ICC profiles, do not accommodate a gamut associated with source profiles. In a typical RGB system, color encoding is completed in an 8-bit system. Thus, a primary color is suitably described with 256 possible levels. In such a system, a pixel is suitably described as a three-dimensional vector, with a magnitude for each component. Thus, by way of example RGB=[0,0,0] is suitably defined as black. Conversely, a value RGB=[255,255,255] is suitably defined as white.

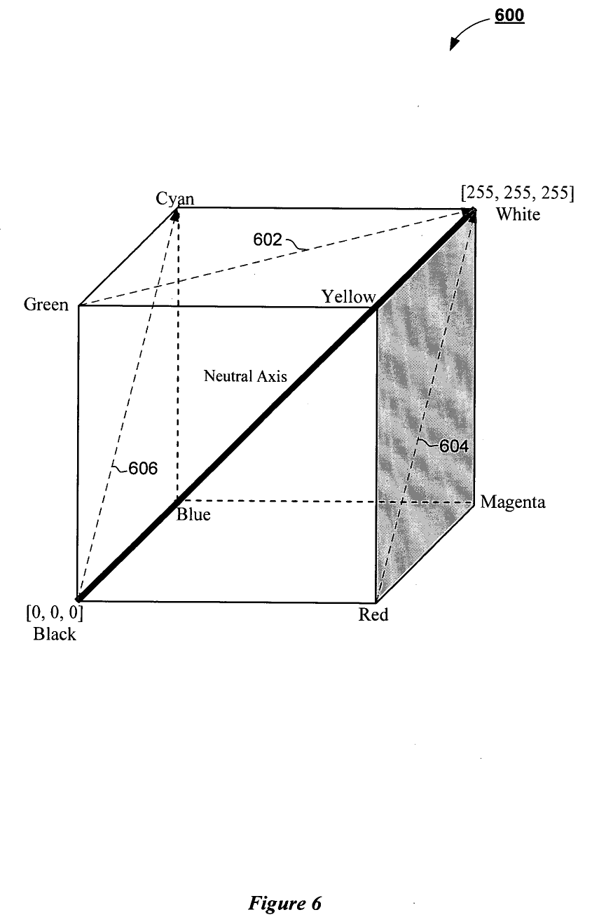

In the illustration of FIG. 6, conversion, such as via a device link profile, is advantageously represented as a three-dimensional array, suitably a cubic array of conversion values forming a lookup table. In current systems, a source profile or color space array describes a transformation between RGB color space to a profile connection space, and then from the profile connection space to a CMYK transform. In the illustrated embodiment, a device link profile is constructed in a cubic manner and typically employs a fixed number of nodes in each direction. By way of example, 17 or 33 nodes in each direction are suitably applied for a 17 cube table. A number of nodes such as 17 or 33 are suitably applied. For a 17 cube table, values from black to red are: 0, 15, 31, 47, 63, 79, 95, 111, 127, 143, 159, 175, 191, 207, 223, 239, 255

It will be appreciated that each of these nodes are typically defined as CMYK. However, it will be appreciated that any such description or space such as RGB, CMYKRB, as whether in any other suitable output values are contemplated.

Each of the aforementioned nodes is suitably CMYK. However, as noted above, it is to be appreciated that any color space such as RGB, CMYKRB and other color spaces are contemplated as will be appreciated by one of ordinary skill in the art. In current systems, a source profile or color space array is typically used to describe a transformation between an input color space, such as RGB, to a profile connection space. A profile connection space is then, in turn, transformed to the output color space, such as CMYK.

The illustration of FIG. 5 represents construction of a suitable three-dimensional conversion array between RGB space and CMYK space. In the illustration, the three-dimensional array 500 includes colors of each of these arrays disposed at vertices of the cubic array. As noted above, black being represented suitably as [0,0,0,] is disposed along an opposite diagonal to that of white, having a value of [255,255,255]. It will be noted that the extension between black and white is referred to as a neutral axis. Similarly, in the illustrated embodiment, red is disposed opposite to cyan, green opposite to magenta, and blue opposite yellow. Values and a pass for progression between various vertices is populated in accordance with the empirically derived document output device characteristics as noted above. A mapping from RGB to CMYK is usually acceptable for near neutral colors to somewhat saturated colors. However, this is typically not as acceptable for highly saturated colors. Such highly saturated colors are generally not mapped to optimal printer or document output device primaries. Ideal mapping from each primary to an optimum amount of CMY colorant depends on factors such as a color or strength of CMY primaries. For example, a blue of a monitor may be printed ideally at 100% cyan plus 70% magenta. A green on a monitor may be printed ideally at 100% yellow and 90% cyan. It is to be appreciated that these numbers will differ by marking technology and color characteristics, as noted above. Also, a selected color mode will change these values as will be detailed further below.

In a preferred embodiment, population of a lookup table for use in connection with a device link profile commences with an empirical determination of a starting value for each node. Ideally, the CMYK value for the white point is maintained at [0,0,0,] and a complimentary black point is defined empirically. Also, values associated with colors on the outer surfaces of the array cube are ideally set at a maximum output of a primary associated with a particular document output device. Therefore, boundaries of the array 600 are ideally set by capabilities of a corresponding output device. In addition, as noted above, particular paths between extremes are device specific and populating with empirically ascertained data and transition pass. In the illustration of FIG. 5, progressions between various vertices, with 602 representing a path between green and white, 604 representing a path between red and whit, and 606 representing a path between cyan and black. Such progression is suitably linear, functional or empirically derived.

In addition to the foregoing, it is often desirable to employ certain modes or effects on a rendered document. Such modes or effects alter the ultimate output from the document rendering device. Conventional effects include those characteristics such as photo, match screen, web colors, vivid, sepia, soft or natural effects. In an alternative embodiment, population of the device link profile array is further alterable to allow for ready inclusion on any such desired effect.

In accordance with the foregoing, an output mode is alterable in connection with desired output characteristics. A weighting of conversion values, such as with a device link profile, is suitable to achieve such a desired output. To accomplish this in a preferred embodiment, CMYK values of nodes are first established. Next, a profile associated with a desired mode is selected, and then concatenated with the previous table of empirical values. The combined nodes values are there for use to modify near-node values so as to allow for inclusion of the desired effect and a smooth progression from neutral to device gamut.

In accordance with the foregoing, the application teaches the provision of a system which allows for fully exploiting the capabilities of a document output device, such as a printer while maintaining visual integrity with an input image. The system of the application further teaches inclusion of desired effects which can be readily incorporated into an output rendered image.

The invention extends to computer programs in the form of source code, object code, code intermediate sources and partially compiled object code, or in any other form suitable for use in the implementation of the invention. Computer programs are suitably standalone applications, software components, scripts or plug-ins to other applications. Computer programs embedding the invention are advantageously embodied on a carrier, being any entity or device capable of carrying the computer program: for example, a storage medium such as ROM or RAM, optical recording media such as CD-ROM or magnetic recording media such as floppy discs. The carrier is any transmissible carrier such as an electrical or optical signal conveyed by electrical or optical cable, or by radio or other means. Computer programs are suitably downloaded across the Internet from a server. Computer programs are also capable of being embedded in an integrated circuit. Any and all such embodiments containing code that will cause a computer to perform substantially the invention principles as described, will fall within the scope of the invention.

The foregoing description of a preferred embodiment of the invention has been presented for purposes of illustration and description. It is not intended to be exhaustive or to limit the invention to the precise form disclosed. Obvious modifications or variations are possible in light of the above teachings. The embodiment was chosen and described to provide the best illustration of the principles of the invention and its practical application to thereby enable one of ordinary skill in the art to use the invention in various embodiments and with various modifications as are suited to the particular use contemplated. All such modifications and variations are within the scope of the invention as determined by the appended claims when interpreted in accordance with the breadth to which they are fairly, legally and equitably entitled.

What is claimed:

1. A color space conversion system comprising:
means adapted for receiving source parameter data representative of an input color gamut of a first multidimensional color space;
means adapted for receiving empirical parameter data associated with color output properties of an associated document output device, which empirical parameter data is associated with a second multidimensional color space; and
conversion table generation means adapted for generating a device link profile in accordance with the source parameter data and the empirical parameter data.

2. The color space conversion system of claim 1 wherein the empirical data includes data corresponding to toner characteristics associated with the document output device.

3. The color space conversion system of claim 2 wherein the conversion table generation means includes:
means adapted for generating a three dimensional data table corresponding to a mapping between the first multidimensional color space and the second multidimensional color space;
means adapted for defining a base white value at a first vertex of the three dimensional table;
means adapted for defining a base black value in accordance with a second vertex of the three dimensional table;
means adapted for defining values associated with surfaces of the three dimensional table in accordance with maximum values associated with the second multidimensional color space; and
means adapted for altering values associated with color progression between vertices of the three dimensional table in accordance with the empirical data.

4. The color space conversion system of claim 3 further comprising:
means adapted for receiving mode data representative of desired output characteristics associated with the conversion; and wherein
the conversion table generation means further includes means adapted for generating the device link profile in accordance with the mode data.

5. The color space conversion system of claim 4 wherein the mode data includes data representative of a desired visual effect associated with an output image.

6. The color space conversion system of claim 3 wherein the first multidimensional color space is RGB and wherein the second multidimensional color space is CYMK, and wherein vertices of the three dimensional table further define base values associated with cyan, yellow, magenta, red, green and blue.

7. A method for color space conversion comprising the steps of:
receiving source parameter data representative of an input color gamut of a first multidimensional color space;
receiving empirical parameter data associated with color output properties of an associated document output device, which empirical parameter data is associated with a second multidimensional color space;
generating a device link profile in accordance with the source parameter data and the empirical parameter data.

8. The method for color space conversion of claim 7 wherein the empirical data includes data corresponding to toner characteristics associated with the document output device.

9. The method for color space conversion of claim 8 wherein the step of generating a device link profile includes the steps of:
generating a three dimensional data table corresponding to a mapping between the first multidimensional color space and the second multidimensional color space;
defining a base white value at a first vertex of the three dimensional table;
defining a base black value in accordance with a second vertex of the three dimensional table;
defining values associated with surfaces of the three dimensional table in accordance with maximum values associated with the second multidimensional color space; and
altering values associated with color progression between vertices of the three dimensional table in accordance with the empirical data.

10. The method for color space conversion of claim 9 further comprising the step of:
receiving mode data representative of desired output characteristics associated with the conversion; and wherein
the step of generating a device link profile includes the step of generating the device link profile in accordance with the mode data.

11. The method for color space conversion of claim 10 wherein the mode data includes data representative of a desired visual effect associated with an output image.

12. The method for color space conversion of claim 9 wherein the first multidimensional color space is RGB and wherein the second multidimensional color space is CYMK, and wherein vertices of the three dimensional table further define base values associated with cyan, yellow, magenta, red, green and blue.

13. A computer-implemented method for color space conversion comprising the steps of:
receiving source parameter data representative of an input color gamut of a first multidimensional color space;
receiving empirical parameter data associated with color output properties of an associated document output device, which empirical parameter data is associated with a second multidimensional color space;
generating a device link profile in accordance with the source parameter data and the empirical parameter data.

14. The computer-implemented method for color space conversion of claim 13 wherein the empirical data includes data corresponding to toner characteristics associated with the document output device.

15. The computer-implemented method for color space conversion of claim 14 wherein the step of generating a device link profile includes the steps of:
generating a three dimensional data table corresponding to a mapping between the first multidimensional color space and the second multidimensional color space;
defining a base white value at a first vertex of the three dimensional table;
defining a base black value in accordance with a second vertex of the three dimensional table;
defining values associated with surfaces of the three dimensional table in accordance with maximum values associated with the second multidimensional color space; and
altering values associated with color progression between vertices of the three dimensional table in accordance with the empirical data.

16. The computer-implemented method for color space conversion of claim 15 further comprising the step of:
receiving mode data representative of desired output characteristics associated with the conversion; and wherein
the step of generating a device link profile includes the step of generating the device link profile in accordance with the mode data.

17. The computer-implemented method for color space conversion of claim 16 wherein the mode data includes data representative of a desired visual effect associated with an output image.

18. The computer-implemented method for color space conversion of claim 15 wherein the first multidimensional color space is RGB and wherein the second multidimensional color space is CYMK, and wherein vertices of the three dimensional table further define base values associated with cyan, yellow, magenta, red, green and blue.
